(19) United States
(12) Patent Application Publication
(10) Pub. No.: US 2016/0037667 A1
(43) Pub. Date: Feb. 4, 2016

(54) INDUSTRIAL COMPUTER CABINET AND CABLE MANAGEMENT STRUCTURE THEREOF

(71) Applicant: AIC INC., Taoyuan Hsien (TW)

(72) Inventor: Wei-Shih WU, Taoyuan Hsien (TW)

(21) Appl. No.: 14/447,955

(22) Filed: Jul. 31, 2014

(51) Int. Cl. H05K 5/02; H05K 7/18

(52) U.S. Cl. CPC H05K 5/0247; H05K 5/0217; H05K 7/18

(57) ABSTRACT

An industrial computer cabinet includes a frame, a pair of slide rails, and a linkage. The pair of slide rails are disposed inside the frame and spaced from each other in a parallel manner. A trench is formed in the swing arm, and a connecting trough is formed inside the linkage. One end of the linkage is connected to the frame and is corresponding to one end of one of the slide rails. The other end of the linkage is pivotably connected to one end of the swing arm, and thereby the swing arm is pivotable to swing.

### BACKGROUND

1. Technical Field

The present invention relates to an industrial computer cabinet, and in particular, to an industrial computer cabinet having a movable cable management structure and the cable management structure.

2. Related Art

A traditional industrial computer usually includes a rack, pairs of slide rails are layered and stacked in the rack. Each of the slide rails is used to support a loading of a host. The host is drawn out by means of the slide rails. Furthermore, a cable management trough is usually formed in the rack to contain cables.

In order to move the host conveniently, no additional cable management structures are disposed between a respective one of the hosts and a respective one of the cable management troughs. Therefore, the cables are hung between the host and the cable management trough and are dragged by the host. Due to the increasing demand for processing data, the hosts are more compactly arranged in the rack. Because of the more compact arrangement of devices and equipment, connectors on the hosts cannot be arranged on the same side and have to be arranged on a front side and a rear side. Therefore, it is necessary to adopt a two-way-pull-out slide rail for the convenience of maintenance. When the host is moved, the hung cables may interfere with other cables connected to a neighboring host, and thereby the cables are easily loosened by pulling and dragging.

In view of the foregoing, the inventor of the present invention made the present invention to improve the above-mentioned issues which are objects the inventor of the present invention aims for.

### BRIEF SUMMARY

It is an object of the present invention to provide an industrial computer cabinet having a movable cable management structure and the cable management structure.

Accordingly, the present invention provides an industrial computer cabinet including a frame, a pair of slide rails, and a linkage. The pair of slide rails is disposed inside the frame and spaced apart from each other in a parallel manner. A trench is formed inside the swing arm, and a connecting trough is formed inside the linkage. One end of the linkage is connected to the frame and is corresponding to one end of one of the slide rails. The other end of the linkage is pivotably connected to one end of the swing arm, and thereby the swing arm is pivotable to swing.

According to the present invention, the industrial computer cabinet and the cable management structure thereof provide the pivotable swing arm to contain the cables, so the cables can be moved along with the host they are connected to, thereby preventing the cables from being loosed or dropped and dragged by the moving host.

### BRIEF DESCRIPTION OF THE DRAWINGS

These and other features and advantages of the various embodiments disclosed herein will be better understood with respect to the following description and drawings, in which like numbers refer to like parts throughout, and in which:

FIG. 1 is a schematic perspective view of the industrial computer cabinet according to the first embodiment of the present invention.

FIG. 2 is an exploded schematic view of a cable management structure of the industrial computer cabinet according to the first embodiment of the present invention.

FIG. 3 is a schematic perspective view of the cable management structure according to FIG. 2.

FIG. 4 is an exploded schematic perspective view of another cable management structure of the industrial computer cabinet according to the first embodiment of the present invention.

FIG. 5 is a schematic perspective view of the cable management structure according to FIG. 4.

FIG. 6 is a reference diagram of a use state of the industrial computer cabinet according to the first embodiment of the present invention.

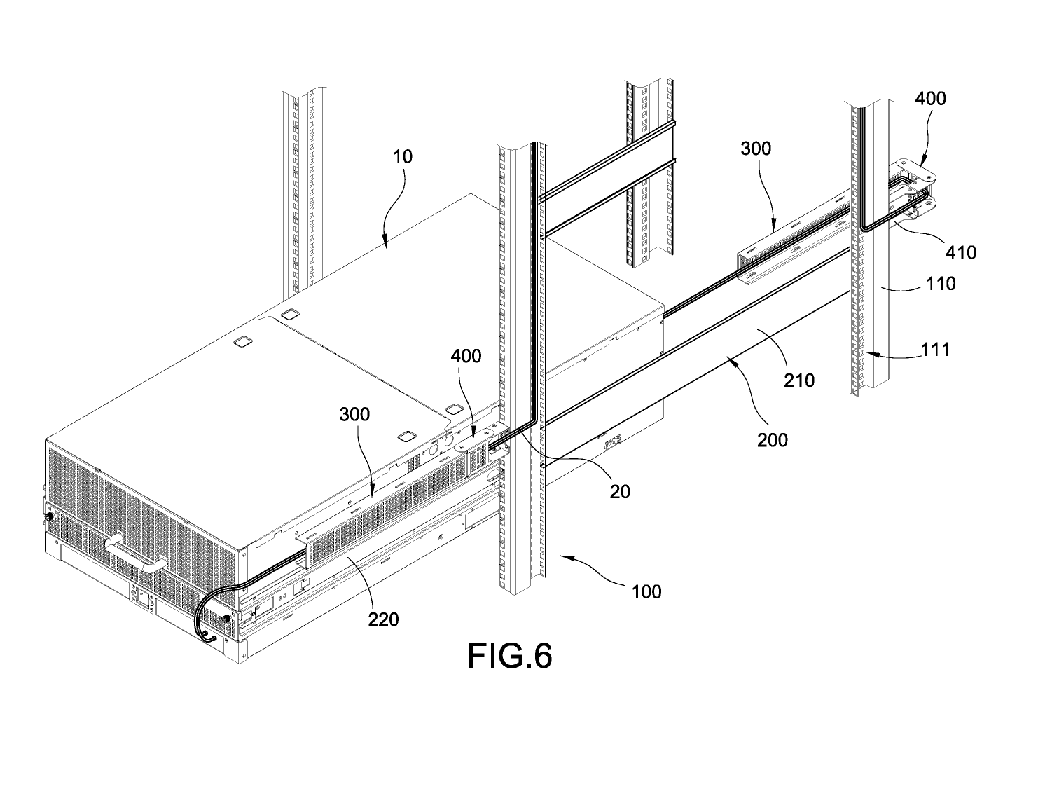

FIG. 7 is a reference diagram of another use state of the industrial computer cabinet according to the first embodiment of the present invention.

FIG. 8 is an exploded schematic perspective view of the industrial computer cabinet according to the second embodiment of the present invention.

FIG. 9 is a schematic perspective view of the industrial computer cabinet according to the second embodiment of the present invention.

### DETAILED DESCRIPTION

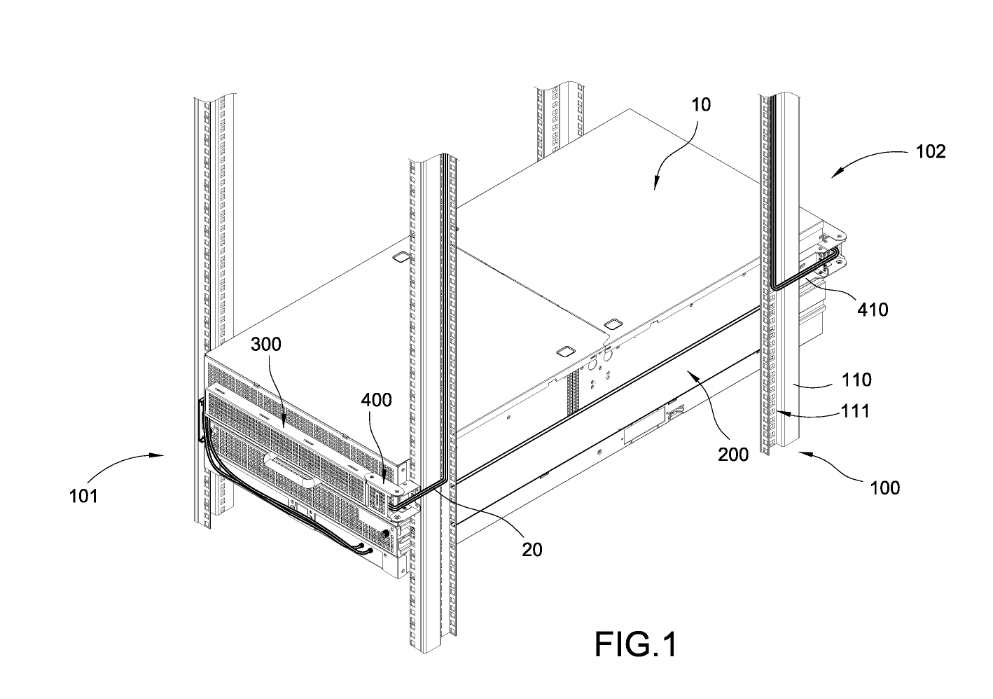

Referring to FIG. 1, the industrial computer cabinet according to the first embodiment of the present invention comprises a frame 100, a pair of slide rails 200, at least one swing arm 300, and at least one linkage 400.

In this embodiment, the frame 100 preferably includes four pillars 110 disposed upright. The pillars 110 are parallel to one another and spaced out to form a rectangular space among the pillars 110, which forms a front side and a rear side corresponding to each other. However, the number of the pillars 110 and the arrangement thereof are not intended to be limited by the foregoing descriptions and the present invention. Each of the pillars 110 is preferably a hollow pillar. A cable management trough 111 is formed inside each of the pillars 110 and extends in a longitudinal direction along the pillar 110.

The pair of slide rails 200 is horizontally disposed inside the frame 100, and spaced apart in parallel relation to each other at two opposite sides of the frame 100. Two ends of the slide rail 200 are respectively disposed at a front side and a rear side of the frame 100. A host 10 is disposed between two of the slide rails 200. A pair of slide rails is described in the present embodiment as exemplified, but the present invention is not limited thereto. A plurality of pairs of slide rails 200 layered and stacked can be disposed in the frame 100. Each pair of the slide rails 200 is used to support one host 10. Therefore, a plurality of hosts 10 can be supported and contained inside the frame 100.

In the present embodiment, each of the slide rails 200 comprises a fixed element 210 and a sliding element 220 respectively. The fixed element 210 and the sliding element 220 both have a long-rod shape. Two fixed element 210 are spaced apart in parallel relation to each other. Two ends of each of the fixed elements 210 are fixed on two of the pillars 110 respectively. Each of the sliding elements 220 is axially slidable on a corresponding one of the fixed elements 210. The sliding element 220 is slidable to protrude from at least one end of the fixed element 210. In the present embodiment, the sliding element 220 is preferably slidable to protrude from any end of the corresponding fixed element 210. The above-mentioned host 10 is horizontally disposed in the frame 100, and two opposite sides of the host 10 are respectively connected to each of the sliding elements 220. Therefore, the host 10 is slidable on the fixed element 210 by means of the sliding element 220 so as to be pushed out from a front side or a rear side of the frame 100.

According to the present embodiment, in correspondence to each host 10, one swing arm 300 is disposed in the front side and the rear side of the host 10, respectively. However, the present invention is not intended to limit the number of the swing arms 300 disposed in correspondence to each host 10.

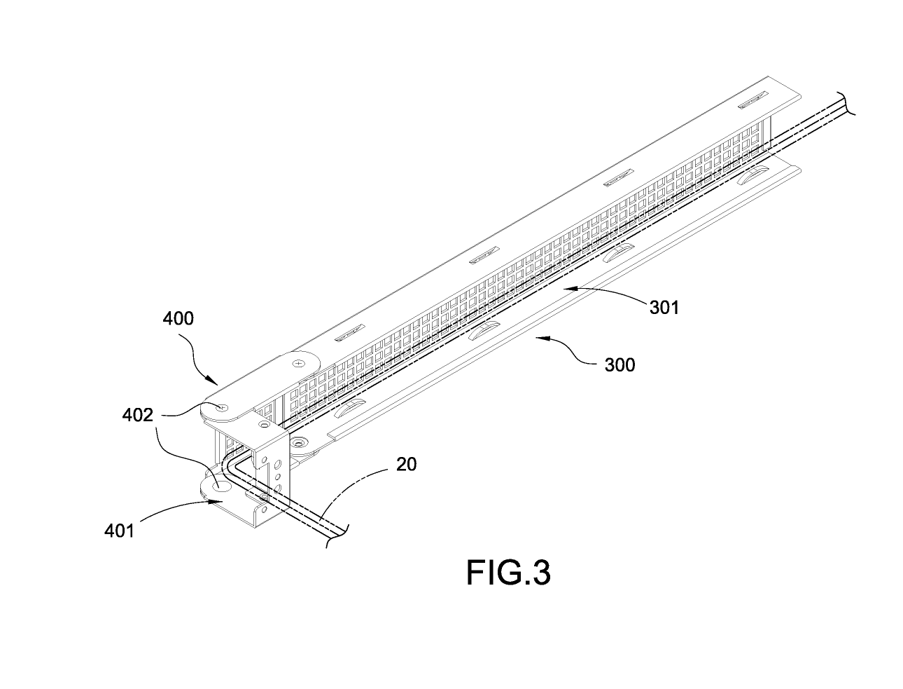

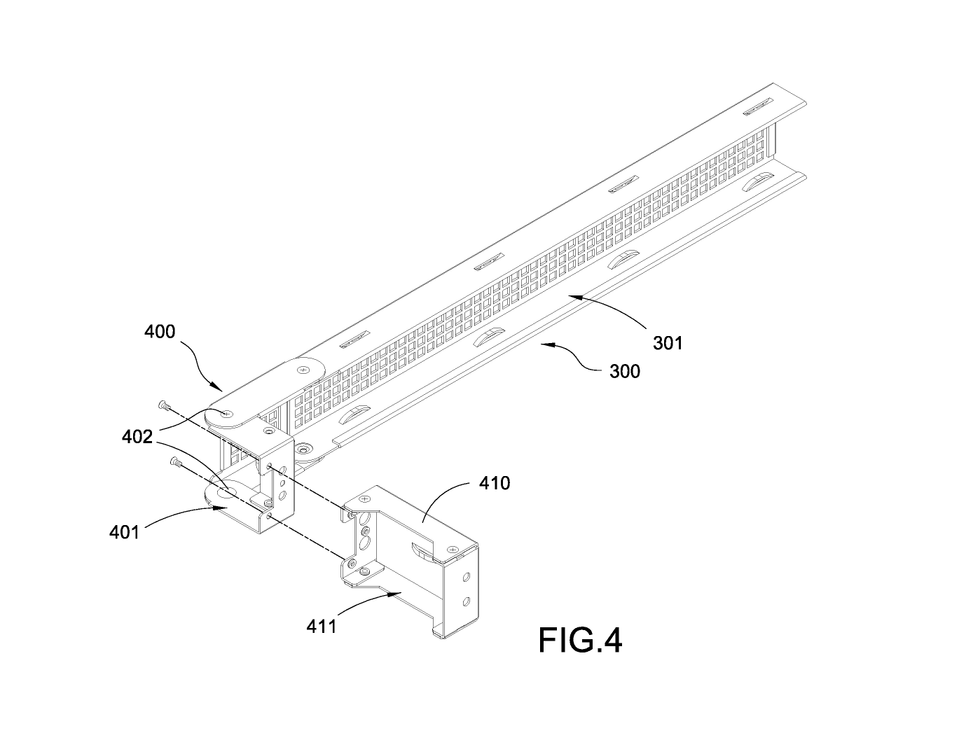

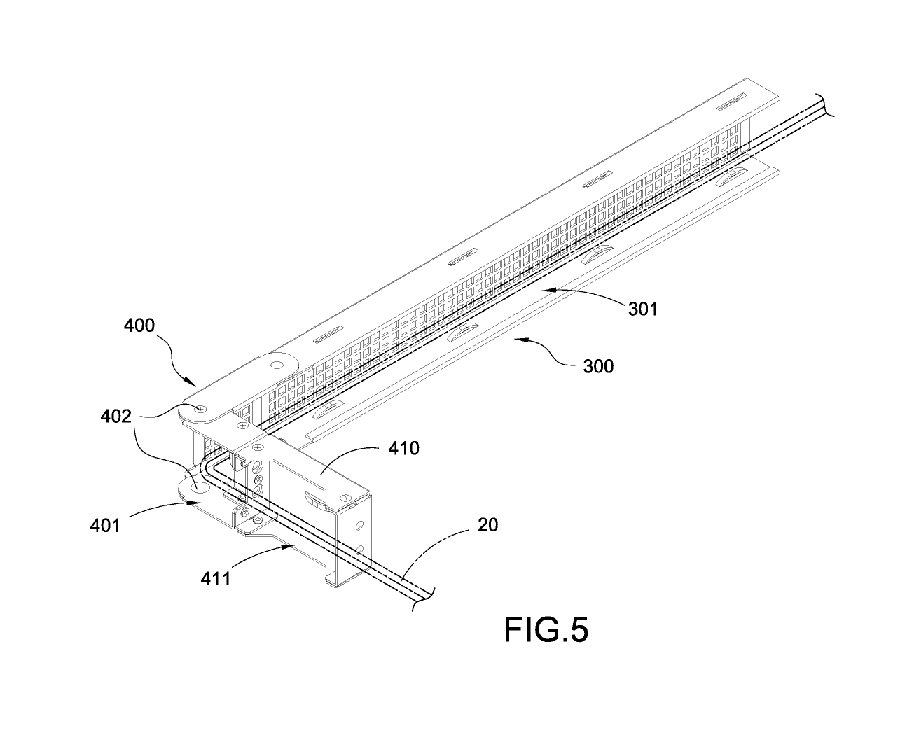

Referring to FIG. 1 to FIG. 5, each of the swing arms 300 is a hollow rod, so a trench 301 is formed inside and extends axially along each of the swing arms 300. A linkage 400 is disposed in correspondence to each of the swing arms 300. Each of the linkage 400 is connected to the frame 100 and the corresponding to the swing arm 300, respectively. A connecting trough 401 is formed inside each of the linkages 400. One end of the linkage 400 is connected to the frame 100 and where it is connected is in correspondence to one end of one of the slide rails 200. The other end of the linkage 400 is pivotably connected to one end of the swing arm 300. Referring to FIG. 1 to FIG. 3, according to the present embodiment, one of the linkages 400 is preferably in screwed connection with the frame 100. Referring to FIGS. 1, 4, and 5, in correspondence to a size of the host 10, another linkage 400 and the frame 100 is fixedly connected to each other by means of a connecting arm 410 between them. The connecting arm 410 is hollow such that a connecting trough 411 is formed inside the connecting arm 410.

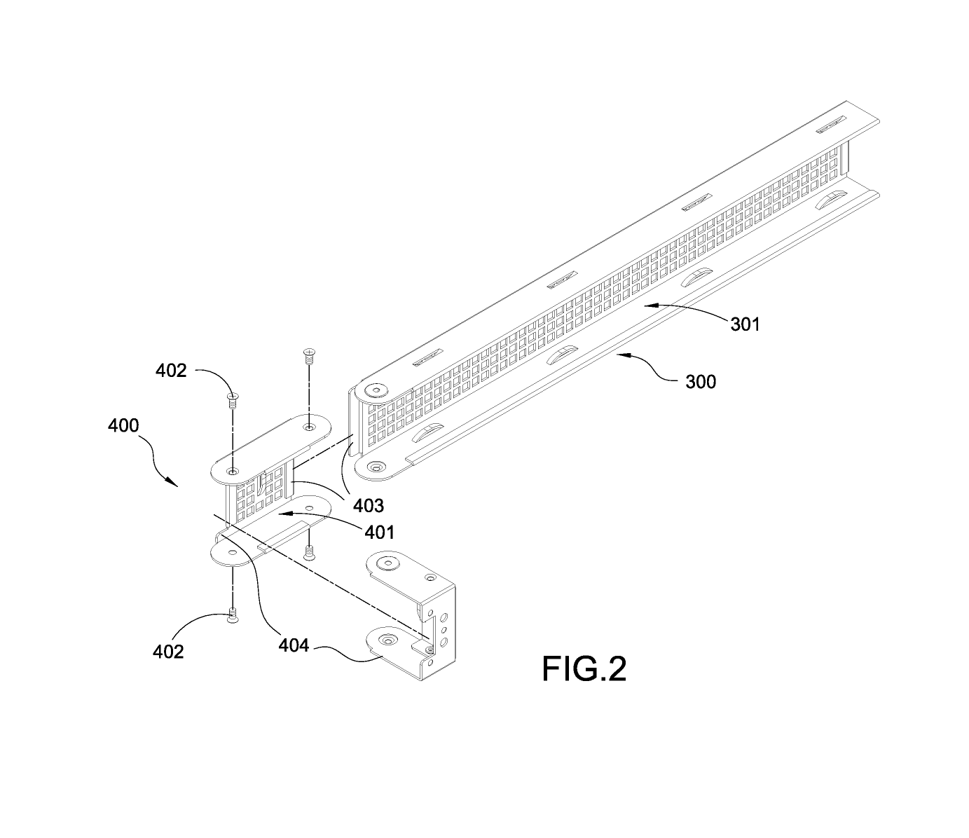

Referring to FIGS. 2 to 5, a middle section of each of the linkages 400 has at least one pivot 402, such that the linkage 400 is pivotable to bend, and the swing arm 300 is pivotable to swing horizontally, so as to be pivoted into the frame 100 and parallel to the slide rail 200. Preferably, a pair of limiting structures 403 is disposed at two sides of a place where the linkage 400 and the swing arm 300 are pivotably connected, so as to limit relative pivoting movement between the linkage 400 and the swing arm 300. A pair of limiting structures 404 is also disposed at two sides of each of the pivots 402 on the middle section of the linkage 400 to limit pivoting and bending movement of the linkage 400.

Referring to FIG. 1, the cable management trough 111 of each of the pillars 110 is used to contain a plurality of cables 20. The cables 20 pass through the connecting trough 401/411 and extend into the swing arm 300. The cables 20 extend out from the other end of the swing arm 300 and are plugged to the host 10 being in correspondence to the swing arm 300. According to the present embodiment, the cables 20 are plugged to opposite sides of the host 10 through the swing arm 300 disposed in correspondence to the front side and the rear side of the frame 100, respectively.

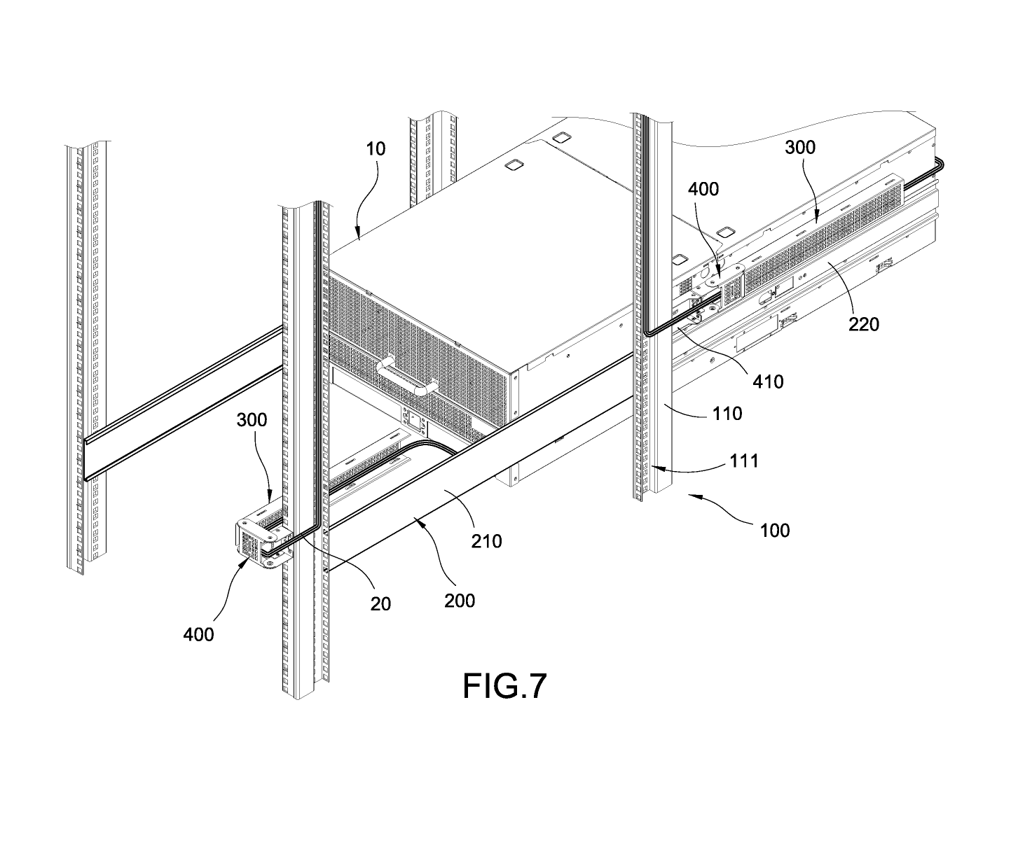

Referring to FIG. 7, when the host 10 is pulled out through the rear side of the frame 100, the swing arm 300 at the rear side of the frame 100 is able to swing outward of the frame 100 so as to allow the host 100 to pass through, and the swing arm 300 is limited by the limiting structure 403/404 so as not to pivot beyond the two sides of the frame 100. Meanwhile, the swing arm 300 on the front side of the frame 100 is pivoted by the linkage 400 to swing into the frame 100, and thereby the cables 20 at the front side of the frame 100 can be moved, along with the host 10, into the frame 100.

According to the present invention, the industrial computer cabinet and the cable management structure thereof contain cables 20 by means of the pivotable swing arm 300. No matter from which side, the front side or the rear side, the host 10 is pulled out of the frame 100, the cables 20 can move along with the host 10 which the cables 20 are plugged into, so as not to be scattered and be dragged by the moving host 10.

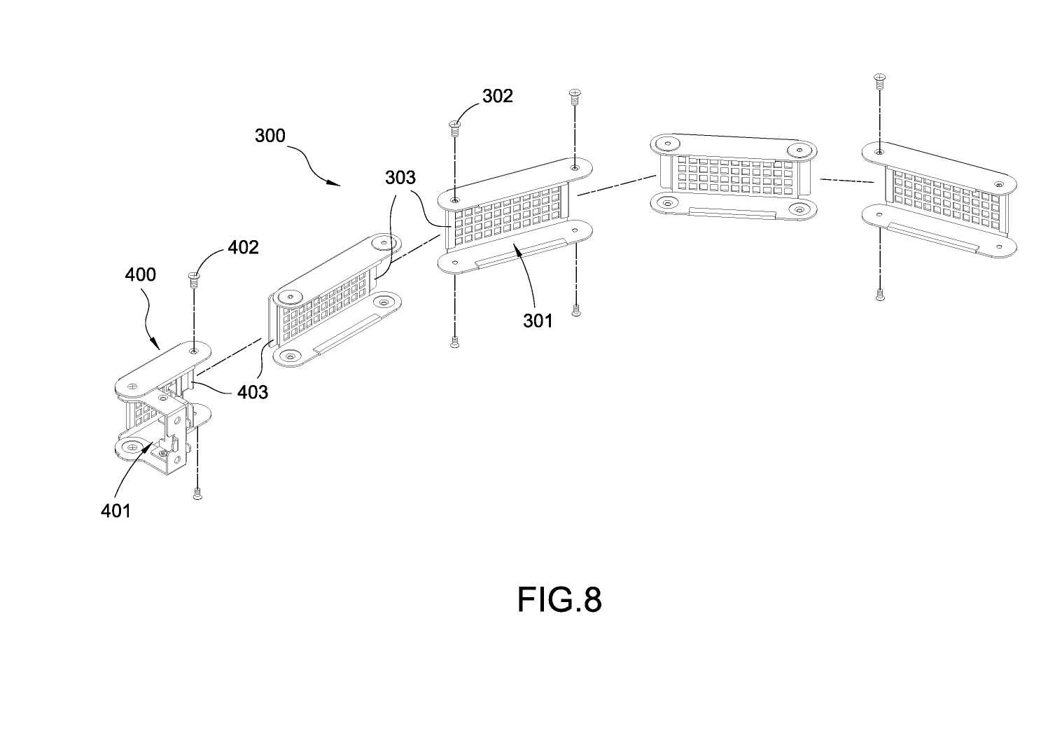

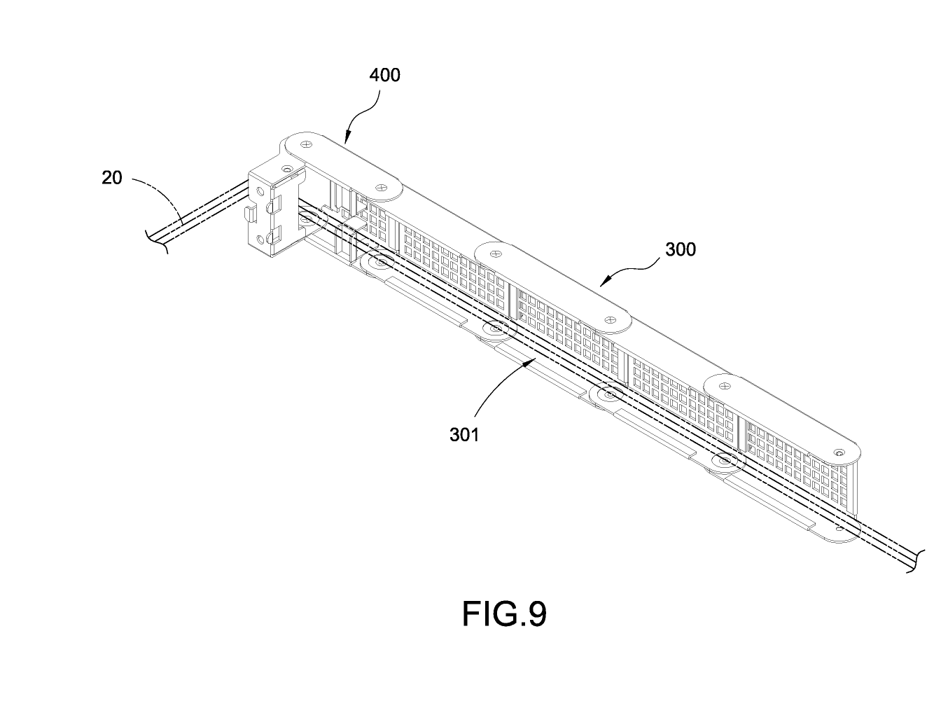

Referring to FIGS. 8 and 9, the second embodiment of the present invention provides an industrial computer cabinet including a frame 100, at least one pair of slide rails 200, at least one swing arm 300, and at least one linkage 400. The structure of the industrial computer cabinet of the second embodiment of the present invention is similar as that of the first embodiment, so the repetition of the same descriptions is omitted here. The differences between the present embodiment and the first embodiment lie in that the middle section of each of the swing arms 300 includes at least one pivot 302, but, according to the present embodiment, a middle section of the swing arm 300 preferably includes a plurality of pivots 302, and the swing arm 300 is pivotable to bend while using the pivots 302. Further, a pair of limiting structures 303 is disposed at two sides of each of the pivots 302, respectively, so as to limit pivoting and bending movement of the swing arm 300.

Although the present invention has been described with reference to the foregoing preferred embodiments, it will be understood that the invention is not limited to the details thereof Various equivalent variations and modifications can still occur to those skilled in this art in view of the teachings of the present invention. Thus, all such variations and equivalent modifications are also embraced within the scope of the invention as defined in the appended claims.

What is claimed is:

1. A cable management structure for an industrial computer cabinet, the industrial computer cabinet including a frame, the cable management structure for the industrial computer cabinet comprising:
a swing arm; and
a linkage, a connecting trough being formed inside the linkage, one end of the linkage being pivotably connected to one end of the swing arm, the other end of the linkage being connected to the frame.

2. The cable management structure for the industrial computer cabinet of claim 1, wherein the middle section of the linkage comprises at least one pivot, and the linkage is pivotable and bendable.

3. The cable management structure for the industrial computer cabinet of claim 2, wherein a pair of limiting structures is disposed at two sides of the pivot to limit pivoting and bending movement of the linkage.

4. The cable management structure for the industrial computer cabinet of claim 1, wherein a pair of limiting structures is disposed at two sides of a place where the swing arm and the linkage are pivotably connected, so as to limit pivoting and bending movement of the linkage.

5. The cable management structure for an industrial cabinet of claim 1, wherein a trench is formed inside the swing arm.

6. The cable management structure for an industrial cabinet of claim 1, wherein a middle section of the swing arm comprises at least one pivot, and the swing arm is pivotable to bend.

7. An industrial computer cabinet, comprising:
a frame;
a pair of slide rails disposed inside the frame, and the pair of the slide rails being disposed spaced apart in parallel relation to each other;
a swing arm; and
a linkage, a connecting trough formed inside the linkage, one end of the linkage connecting to the frame and corresponding to one end of one of the slide rails, the other end of the linkage is pivotably connected to one end of the swing arm, thereby the swing arm is pivotable to swing.

8. The industrial computer cabinet of claim 7, wherein the linkage is pivotably connected to the frame.

9. The industrial computer cabinet of claim 7, wherein a middle section of the linkage comprises at least one pivot, and the pivot is pivotable to bend.

10. The industrial computer cabinet of claim 9, wherein a pair of limiting structures are disposed at two sides of the pivot to limit pivoting and bending movement of the linkage.

11. The industrial computer cabinet of claim 7, wherein each of the slide rails comprises a fixed element and a sliding element respectively, two ends of each of the fixed elements are fixed on the frame respectively, each of the sliding elements is axially slidable on a corresponding one of the fixed elements, and each of the sliding elements is slidable to protrude from one end of a corresponding one of the fixed elements.

12. The industrial computer cabinet of claim 7, wherein the swing arm is pivotable to pivot into the frame.

13. The industrial computer cabinet of claim 7, wherein each of the slide rails comprises a fixed element and a sliding element respectively, two ends of each of the fixed elements are fixed to the frame respectively, each of the sliding elements is axially slidable on a corresponding one of the fixed elements, and each of the sliding elements is slidable to protrude from any end of a corresponding one of the fixed elements.

14. The industrial computer cabinet of claim 13, wherein the swing arm and the linkage which the swing arm is correspondingly pivotably connected to are provided in a plural number.

15. The industrial computer cabinet of claim 14, wherein the linkages are disposed on the frame and disposed corresponding to two ends of the slide rail respectively.

16. The industrial computer cabinet of claim 7, wherein a connecting arm is connected between the linkage and the frame.

17. The industrial computer cabinet of claim 7, wherein a trench is formed inside the swing arm.

18. The industrial computer cabinet of claim 7, wherein a middle section of the swing arm comprises at least one pivot, and the swing arm is pivotable to bend.

19. The industrial computer cabinet of claim 18, wherein a limiting structure is disposed at two sides of the pivot to limit pivoting and bending movement of the swing arm.
